(19) United States
(12) Patent Application Publication
(10) Pub. No.: US 2013/0083253 A1
(43) Pub. Date: Apr. 4, 2013

(54) TELEVISION AND ELECTRONIC APPARATUS

(71) Applicants: Shogo Maeshima, Ome-shi (JP); Shingo Koide, Tachikawa-shi (JP); Toshikazu Shiroishi, Hamura-shi (JP)

(72) Inventors: Shogo Maeshima, Ome-shi (JP); Shingo Koide, Tachikawa-shi (JP); Toshikazu Shiroishi, Hamura-shi (JP)

(21) Appl. No.: 13/531,267

(22) Filed: Jun. 22, 2012

(30) Foreign Application Priority Data
Sep. 30, 2011 (JP) 2011-217721

(51) Int. Cl. H04N 5/66; H05K 7/20

(52) U.S. Cl. 348/739; 361/695; 348/E05.133

(57) ABSTRACT

According to one embodiment, an electronic apparatus includes a housing, a first radiating portion in the housing, a second radiating portion in the housing, a first heat pipe thermally connected to the first radiating portion, a second heat pipe including a portion crossing the first heat pipe, the second heat pipe thermally connected to the second radiating portion, and a fan configured to blow air to at least one of the first radiating portion and the second radiating portion.

### CROSS-REFERENCE TO RELATED APPLICATIONS

This application is based upon and claims the benefit of priority from prior Japanese Patent Application No. 2011-217721, filed Sep. 30, 2011, the entire contents of which are incorporated herein by reference.

### FIELD

Embodiments described herein relate generally to electronic apparatuses including televisions.

### BACKGROUND

An electronic apparatus is proposed in which two heat pipes overlap each other.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view of a television according to a first embodiment;

FIG. 2 is an exemplary rear view of the internal structure of the television illustrated in FIG. 1;

FIG. 3 is an exemplary rear view of the internal structure of a television according to a second embodiment;

FIG. 4 is an exemplary perspective view of an electronic apparatus according to a third embodiment;

FIG. 5 is an exemplary cross-sectional view of the internal structure of the electronic apparatus illustrated in FIG. 4;

FIG. 6 is an exemplary cross-sectional view of the internal structure of an electronic apparatus related to the electronic apparatus illustrated in FIG. 4;

FIG. 7 is an exemplary plan view of heat pipes of the electronic apparatus illustrated in FIG. 5;

FIG. 8 is an exemplary plan view of heat pipes of the electronic apparatus illustrated in FIG. 6;

FIG. 9 is an exemplary plan view of heat pipes of the electronic apparatus illustrated in FIG. 5;

FIG. 10 is an exemplary plan view of heat pipes of the electronic apparatus illustrated in FIG. 6;

FIG. 11 is an exemplary perspective view of the heat radiating structure of an electronic apparatus according to a fourth embodiment;

FIG. 12 is an exemplary front view of the heat radiating structure illustrated in FIG. 11;

FIG. 13 is an exemplary perspective view of the heat radiating structure of an electronic apparatus according to a fifth embodiment;

FIG. 14 is an exemplary cross-sectional view of the heat radiating structure illustrated in FIG. 13;

FIG. 15 is an exemplary cross-sectional view of the heat radiating structure of an electronic apparatus according to a sixth embodiment;

FIG. 16 is an exemplary cross-sectional view of the internal structure of an electronic apparatus according to a seventh embodiment;

FIG. 17 is an exemplary cross-sectional view of the internal structure of an electronic apparatus according to an eighth embodiment;

FIG. 18 is an exemplary cross-sectional view of an electronic apparatus according to a ninth embodiment;

FIG. 19 is an exemplary cross-sectional view of the internal structure of an electronic apparatus according to a tenth embodiment;

FIG. 20 is an exemplary cross-sectional view of the internal structure of an electronic apparatus according to a eleventh embodiment; and

FIG. 21 is an exemplary cross-sectional view of the internal structure of an electronic apparatus according to a twelfth embodiment.

### DETAILED DESCRIPTION

Various embodiments will be described hereinafter with reference to the accompanying drawings.

In general, according to one embodiment, an electronic apparatus comprises a housing, a first radiating portion in the housing, a second radiating portion in the housing, a first heat pipe thermally connected to the first radiating portion, a second heat pipe comprising a portion crossing the first heat pipe, the second heat pipe thermally connected to the second radiating portion, and a fan configured to blow air to at least one of the first radiating portion and the second radiating portion.

Hereinafter, embodiments will be described with reference to the accompanying drawings.

### First Embodiment

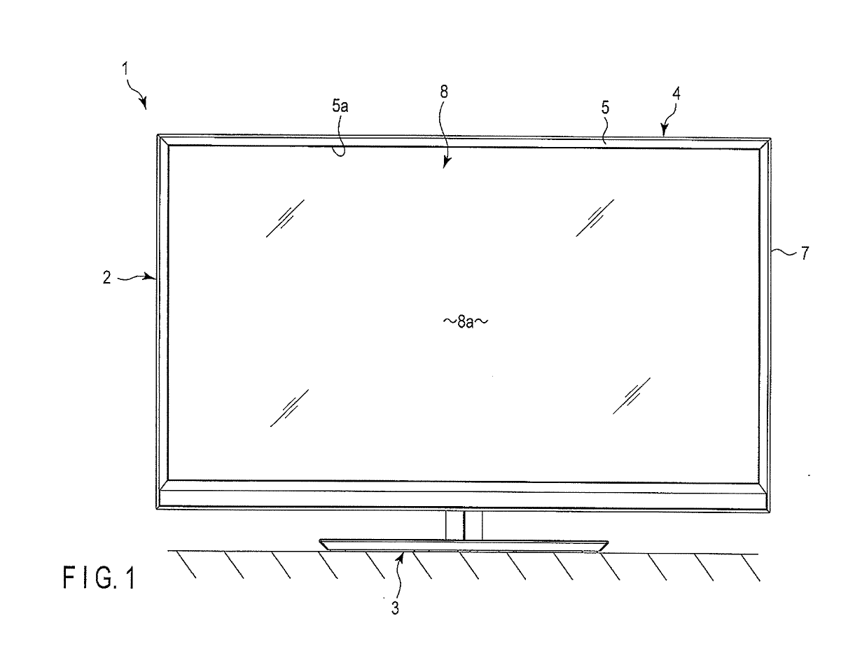

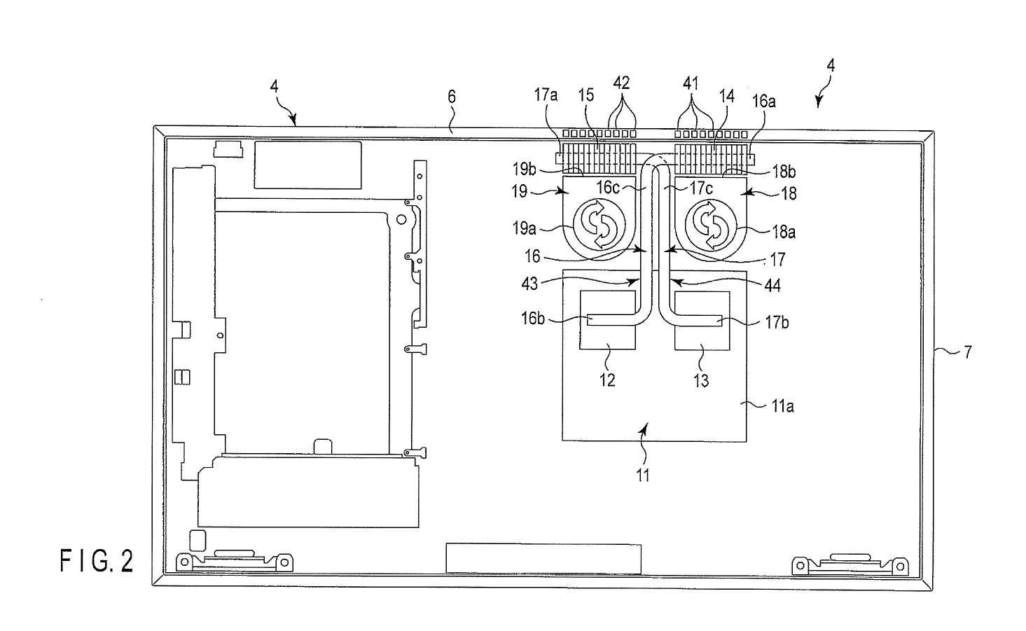

FIGS. 1 and 2 illustrate a television 1 according to a first embodiment. The television 1 is an example of an “electronic apparatus”. As illustrated in FIG. 1, the television 1 includes a display unit 2 and a stand 3 supporting the display unit 2.

As illustrated in FIGS. 1 and 2, the display unit 2 includes a housing 4. The housing 4 has a flat box shape including a front wall 5, a back wall 6, and a peripheral wall 7. The housing 4 accommodates a display 8. The display 8 includes a display screen 8a. The display screen 8a is exposed to the outside through an opening portion 5a in the front wall 5 of the housing 4.

As illustrated in FIG. 2, the housing 4 includes a circuit board 11, a first heat-generating element 12, a second heat-generating element 13, a first radiating portion 14, a second radiating portion 15, a first heat pipe 16, a second heat pipe 17, a first fan 18, and a second fan 19. The components have substantially the same detailed structures as those according to a third embodiment. Therefore, the detailed description of the components will be described in the third embodiment.

### Second Embodiment

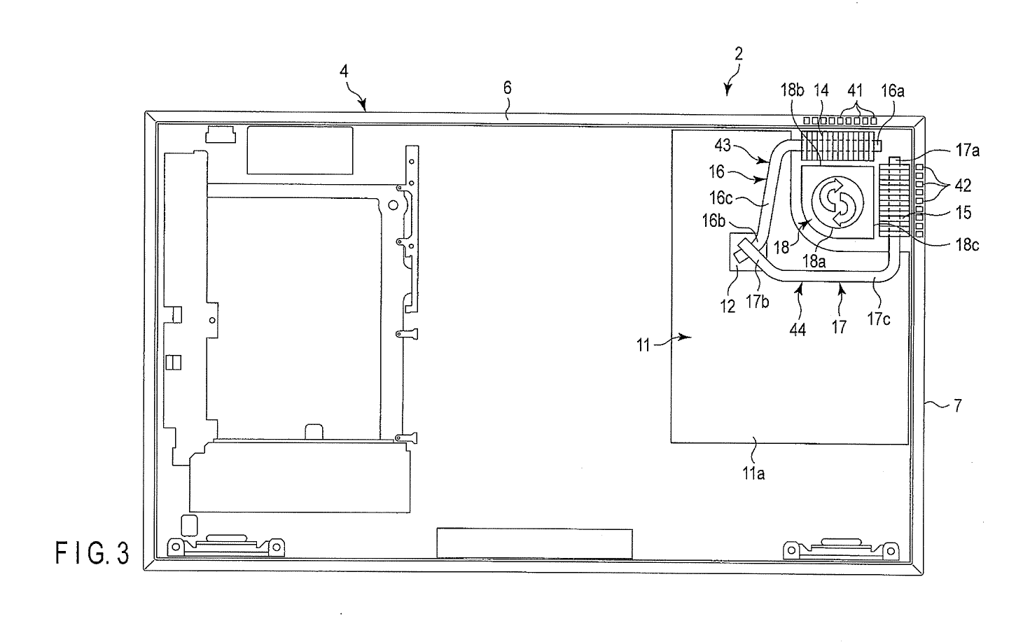

FIG. 3 illustrates a television 1 according to a second embodiment. In the embodiment, components having the same or similar functions as those in the first embodiment are denoted by the same reference numerals, and the description thereof will not be repeated.

As illustrated in FIG. 3, a housing 4 includes a circuit board 11, a heat-generating element 12, a first radiating portion 14, a second radiating portion 15, a first heat pipe 16, a second heat pipe 17, and a fan 18. The components have substantially the same detailed structures as those according to a tenth embodiment. Therefore, the detailed description of the components will be described in the tenth embodiment.

### Third Embodiment

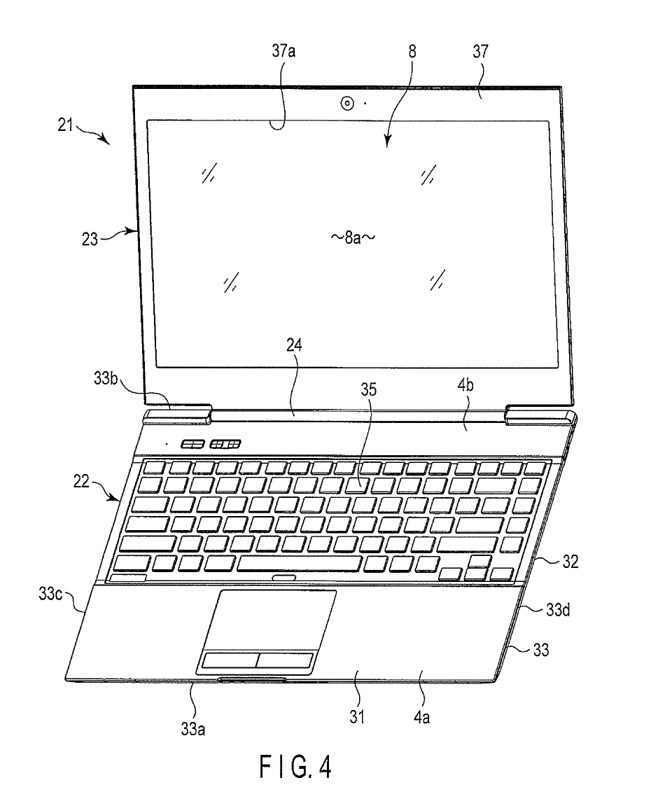

Next, an electronic apparatus 21 according to a third embodiment will be described with reference to FIGS. 4 to 10. The electronic apparatus 21 according to the embodiment is, for example, a notebook portable computer (i.e., notebook PC). The electronic apparatus 21 includes a first unit 22, a second unit 23, and a hinge portion 24. The first unit 22 is, for example, a main unit including a main board. The first unit 22 includes a first housing 4.

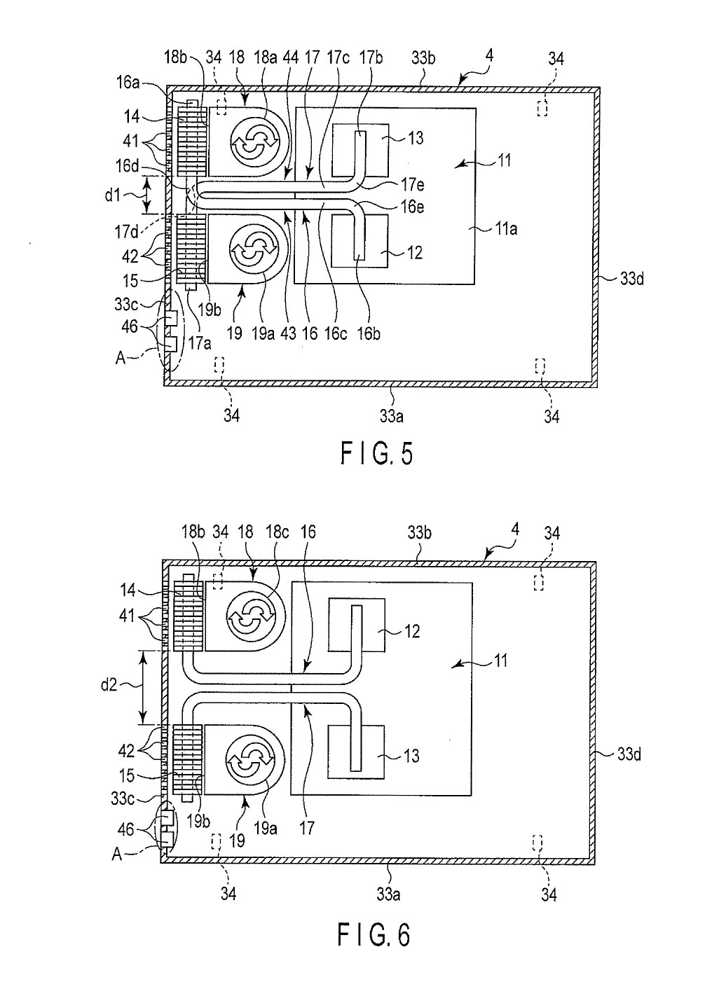

The first housing 4 includes an upper wall 31, a lower wall 32, and a peripheral wall 33 and has a flat box shape. The lower wall 32 faces the top surface of a desk (i.e., outer mounting surface) when the electronic apparatus 21 is placed on the desk. A plurality of leg portions 34 (i.e. support portions) that come into contact with the top surface of the desk and support the electronic apparatus 21 are provided on the lower wall 32 (see FIG. 5). The upper wall 31 is opposite to the lower wall 32 with a space therebetween and extends substantially in parallel to the lower wall 32. An input portion 35 (i.e., input receiving portion) is provided on the upper wall 31. An example of the input portion 35 is a keyboard. The “input portion” may be a touch panel input device or other input devices.

The peripheral wall 33 rises with respect to the lower wall 32 and connects the peripheral edge of the lower wall 32 and the peripheral edge of the upper wall 31. The peripheral wall 33 may not have a defined boundary with the lower wall 32. It may be connected to the lower wall 32 in a curved surface shape. At least a portion of the peripheral wall 33 extends in the thickness direction of the first housing 4.

As illustrated in FIG. 4, the first housing 4 includes a first end portion 4a and a second end portion 4b. The first end portion 4a is, for example, a front end portion. The second end portion 4b is, for example, a rear end portion and is opposite to the first end portion 4a. In the specification, the front, rear, left, and right sides are defined as viewed from the user. That is, the side close to the user is defined as the “front side” and the side away from the user is defined as the “rear side”.

The peripheral wall 33 includes a front wall 33a, a rear wall 33b, a first side wall 33c (e.g., left wall), and a second side wall 33d (e.g., right wall). The front wall 33a is disposed at the first end portion 4a and extends in the longitudinal direction (e.g., width direction) of the housing 4. The rear wall 33b is disposed at the second end portion 4b and extends substantially in parallel to the front wall 33a. The first side wall 33c and the second side wall 33d extend in a direction crossing (for example, a direction substantially perpendicular to) the front wall 33a and the rear wall 33b, and connect the front wall 33a and the rear wall 33b.

The second unit 23 is, for example, a display portion, and includes a second housing 37 and a display 8 accommodated in the second housing 37. The display 8 is, for example, a liquid crystal display, and is not limited thereto. The display 8 includes a display screen 8a on which images are displayed. The second housing 37 includes an opening portion 37a through which the display screen 8a is exposed to the outside.

The second housing 37 is rotatably (i.e., openably) connected to the rear end portion of the first housing 4 by the hinge portion 24. In this way, the electronic apparatus 21 can be rotated between a first state in which the first unit 22 and the second unit 23 overlap each other and a second state in which the first unit 22 and the second unit 23 are opened.

Next, the inside of the first housing 4 (hereinafter, simply referred to as the housing 4) will be described in detail.

As illustrated in FIG. 5, the housing 4 includes first exhaust holes 41 (i.e., first opening portions) and second exhaust holes 42 (i.e., second opening portions). In the embodiment, the first exhaust holes 41 and the second exhaust holes 42 are provided in the first side wall 33c. However, the first and second exhaust holes may be provided in other walls (for example, the rear wall 33b or the second side wall 33d).

The housing 4 accommodates a circuit board 11, a first heat-generating element 12, a second heat-generating element 13, a first radiating portion 14, a second radiating portion 15, a first heat pipe 16, a second heat pipe 17, a first fan 18, and a second fan 19.

The circuit board 11 is substantially parallel to the upper wall 31. The circuit board 11 is electrically connected to the display 8. The circuit board 11 includes a first surface 11a and a second surface 11b opposite to the first surface 11a. In the embodiment, the first heat-generating element 12 and the second heat-generating element 13 are mounted on the same surface (for example, the first surface 11a) of the circuit board 11. In addition, the first heat-generating element 12 and the second heat-generating element 13 may be separately mounted on the first surface 11a and the second surface 11b.

An example of the first heat-generating element 12 is a central processing unit (CPU). An example of the second heat-generating element 13 is a video graphics array (VGA). The energy consumption (i.e., the amount of heat generated or power consumption) of the first heat-generating element 12 is more than the energy consumption (i.e., the amount of heat generated) of the second heat-generating element 13. The first heat-generating element 12 and the second heat-generating element 13 are not limited to the above-mentioned examples, and may be various kinds of components (electronic components) requiring heat radiation. The energy consumption of the first heat-generating element 12 may be less than that of the second heat-generating element 13.

As illustrated in FIG. 5, the electronic apparatus 21 includes two heat radiating systems. A first heat radiating system 43 (i.e., first cooling device) has a remote heat exchanger (RHE) structure and includes the first radiating portion 14, the first heat pipe 16, and the first fan 18. The first heat radiating system 43 corresponds to the first heat-generating element 12 and accelerates the heat radiation of the first heat-generating element 12.

A second heat radiating system 44 (i.e., second cooling device) has another remote heat exchanger (RHE) structure and includes the second radiating portion 15, the second heat pipe 17, and the second fan 19. In the embodiment, the first heat radiating system 43 and the second heat radiating system 44 are independent from each other.

As illustrated in FIG. 5, in the embodiment, in the first heat radiating system 43 and the second heat radiating system 44, the positions of the radiating portions (e.g., heat sinks) are reversed and the heat pipes intersect (e.g., cross) each other, which will be described in detail below.

As illustrated in FIG. 5, each of the first radiating portion 14 and the second radiating portion 15 is a heat sink. A specific example of each of the first radiating portion 14 and the second radiating portion 15 is a fin unit including a plurality of fins. The first radiating portion 14 faces the first exhaust holes 41. The second radiating portion 15 faces the second exhaust holes 42.

The first radiating portion 14 and the second radiating portion 15 are reversed each other, for example, as compared to the arrangement illustrated in FIG. 6. Therefore, the first heat-generating element 12 is closer to the second radiating portion 15 than to the first radiating portion 14. The second heat-generating element 13 is closer to the first radiating portion 14 than to the second radiating portion 15.

As illustrated in FIG. 5, the first fan 18 faces the first radiating portion 14 and blows air to the first radiating portion 14. The first fan 18 is, for example, a centrifugal fan. The first fan 18 includes an air intake 18a which is provided in at least one of the upper surface and the lower surface and a discharge hole 18b through which air is blown to the first radiating portion 14. The first fan 18 draws air from the air intake 18a and discharges air from the discharge hole 18b.

The second fan 19 faces the second radiating portion 15 and blows air to the second radiating portion 15. The second fan 19 is, for example, a centrifugal fan. The second fan 19 includes an air intake 19a which is provided in at least one of the upper surface and the lower surface and a discharge hole 19b through which air is blown to the second radiating portion 15. The second fan 19 draws air from the air intake 19a and discharges air from the discharge hole 19b.

Each of the first heat pipe 16 and the second heat pipe 17 is an example of a “heat transfer portion”, a “heat transfer component”, a “heat transfer member”, a “radiating portion”, a “heat radiating component”, a “heat radiating member”, a “heat receiving portion (i.e., second heat receiving portion)”, a “heat receiving component (i.e., second heat receiving component)”, a “heat receiving member (i.e., second heat receiving member)”, and a “metal member”. These components (i.e., members) are not limited to the heat pipe, and may be heat radiating metal plates or carbon fiber members.

As illustrated in FIG. 5, the first heat pipe 16 extends between the first radiating portion 14 and the first heat-generating element 12, and thermally connects the first radiating portion 14 and the first heat-generating element 12. The first heat pipe 16 includes a first end portion 16a (i.e., first portion), a second end portion 16b (i.e., second portion), and a central portion 16c (i.e., third portion).

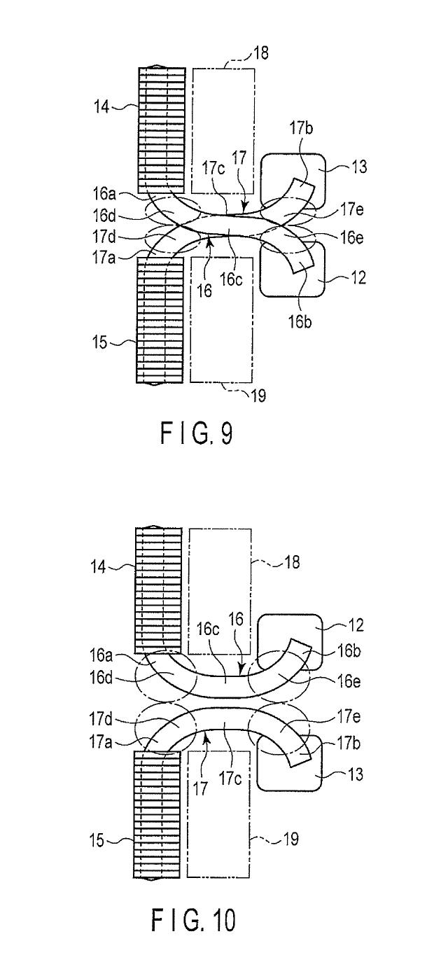

The first end portion 16a is thermally connected to the first radiating portion 14. The second end portion 16b is opposite to the first end portion 16a and is thermally connected to the first heat-generating element 12. The central portion 16c is between the first end portion 16a and the second end portion 16b. As illustrated in FIG. 9, the central portion 16c is inclined away from the first fan 18 while extending from the first end portion 16a to the second end portion 16b.

As illustrated in FIG. 9, the first heat pipe 16 further includes a first curved portion 16d (i.e., first curved line portion) and a second curved portion 16e (i.e., second curved line portion). Each of the first curved portion 16d and the second curved portion 16e is an example of a “non-linear portion”. The first curved portion 16d is connected to the first end portion 16a (i.e., provided at the first end portion 16a). The first curved portion 16a is bent from the central portion 16c to the first radiating portion 14.

The second curved portion 16e is connected to the second end portion 16b (i.e., provided at the second end portion 16b). The second curved portion 16e is bent from the central portion 16c to the first heat-generating element 12. That is, the first curved portion 16d and the second curved portion 16e are bent in the opposite direction. For example, the first curved portion 16d and the second curved portion 16e are connected to each other. That is, in the example of the first heat pipe 16, no linear portion is provided between the first curved portion 16d and the second curved portion 16e.

As illustrated in FIG. 5, the second heat pipe 17 extends between the second radiating portion 15 and the second heat-generating element 13, and thermally connects the second radiating portion 15 and the second heat-generating element 13. The second heat pipe 17 includes a first end portion 17a (i.e., first portion), a second end portion 17b (i.e., second portion), and a central portion 17c (i.e., third portion).

The first end portion 17a is thermally connected to the second radiating portion 15. The second end portion 17b is opposite to the first end portion 17a and is thermally connected to the second heat-generating element 13. The central portion 17c is between the first end portion 17a and the second end portion 17b. As illustrated in FIG. 9, the central portion 17c is inclined away from the second fan 19 while extending from the first end portion 17a to the second end portion 17b.

As illustrated in FIG. 9, the second heat pipe 17 further includes a first curved portion 17d (i.e., first curved line portion) and a second curved portion 17e (i.e., second curved line portion). Each of the first curved portion 17d and the second curved portion 17e is an example of a “non-linear portion”. The first curved portion 17d is connected to the first end portion 17a (i.e., provided at the first end portion 17a). The first curved portion 17d is bent from the central portion 17c to the second radiating portion 15.

The second curved portion 17e is connected to the second end portion 17b (i.e., provided at the second end portion 17b). The second curved portion 17e is bent from the central portion 17c to the second heat-generating element 13. That is, the first curved portion 17d and the second curved portion 17e are bent in the opposite direction. For example, the first curved portion 17d and the second curved portion 17e are connected to each other. That is, in the example of the second heat pipe 17, no linear portion is provided between the first curved portion 17d and the second curved portion 17e.

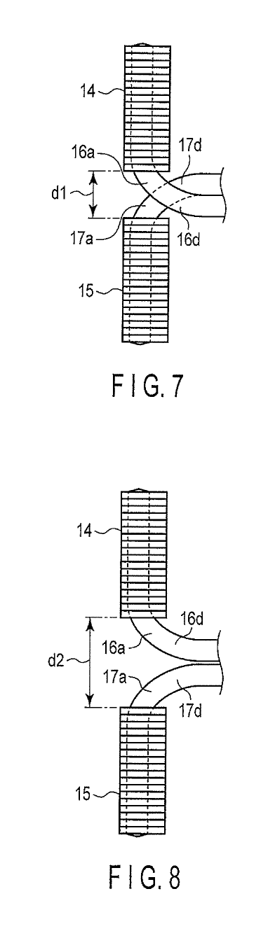

As illustrated in FIGS. 5 and 7, in the embodiment, the first heat pipe 16 and the second heat pipe 17 intersect each other. That is, the first heat pipe 16 has a portion crossing the second heat pipe 17. The second heat pipe 17 has a portion crossing the first heat pipe 16.

Specifically, as illustrated in FIGS. 7 and 9, a portion of the first heat pipe 16 intersects at least a part of the non-linear portion (for example, the first curved portion 17d and the second curved portion 17e) of the second heat pipe 17. A portion of the second heat pipe 17 intersects at least a part of the non-linear portion (for example, the first curved portion 16d and the second curved portion 16e) of the first heat pipe 16.

In addition, as illustrated in FIGS. 7 and 9, in the embodiment, at least a part of the first curved portion 16d of the first heat pipe 16 intersects at least a part of the first curved portion 17d of the second heat pipe 17. At least a part of the second curved portion 16e of the first heat pipe 16 intersects at least a part of the second curved portion 17e of the second heat pipe 17.

As described above, in the embodiment, the first heat-generating element 12 and the second heat-generating element 13 are mounted on the same surface (for example, the first surface 11a) of the circuit board 11. Therefore, the first heat pipe 16 and the second heat pipe 17 are provided above the same surface (for example, the first surface 11a) of the circuit board 11. That is, the first heat pipe 16 and the second heat pipe 17 face the same surface (for example, the first surface 11a) of the circuit board 11.

In the embodiment, the first heat pipe 16 is located between the second heat pipe 17 and the circuit board 11. That is, the second heat pipe 17 extends over (i.e., crosses) the first heat pipe 16 on the side opposite to the circuit board 11.

In this way, the first heat pipe 16 is closer to the surface of the circuit board 11 than the second heat pipe 17 at least at the intersection between the first heat pipe 16 and the second heat pipe 17. The first heat pipe 16 extends between the first radiating portion 14 and the first heat-generating element 12 without interfering with the second heat pipe 17. The first heat pipe 16 is shorter than the second heat pipe 17.

The first heat pipe 16 and the second heat pipe 17 do not contact each other and have a gap therebetween. As illustrated in FIG. 5, a plurality of leg portions 34 for supporting the housing 4 are provided on the housing 4. The leg portions 34 are provided at positions other than (so as to avoid) the intersection between the first heat pipe 16 and the second heat pipe 17. In this way, the contact between the first heat pipe 16 and the second heat pipe 17 due to stress from the leg portions 34 can be suppressed.

As illustrated in FIG. 5, connectors 46 serving as external I/O ports are provided in the housing 4. The connectors 46 are an example of an “external connection component”, a “functional component”, and an “electronic component”. The connectors 46 are provided on the wall (for example, the first side wall 33c) in which the exhaust holes 41 and 42 are provided.

According to this structure, the size of the electronic apparatus 21 can be reduced, and the cooling efficiency thereof can be improved. For comparison, FIG. 6 illustrates a heat radiating structure in which the heat pipes do not intersect each other. There is a limit to the curvature of the heat pipe based on the diameter of the heat pipe. That is, it is difficult to bend the heat pipe at a curvature less than a predetermined value. Therefore, as illustrated in FIG. 6, when the first curved portion 16d of the first heat pipe 16 and the first curved portion 17d of the second heat pipe 17 are arranged horizontally, a relatively large space is needed.

Therefore, in the structure in which the heat pipes do not intersect each other, a distance d2 between the first radiating portion 14 and the second radiating portion 15 needs to be large. Therefore, it is not easy to ensure a large connector mounting region A in the housing 4, and it is difficult to reduce the size of the electronic apparatus 21.

In contrast, in the embodiment, as illustrated in FIG. 5, the first heat pipe 16 and the second heat pipe 17 extend so as to intersect each other. In this way, the first curved portion 16d of the first heat pipe 16 and the first curved portion 17d of the second heat pipe 17 can avoid being arranged horizontally, and the distance d1 between the first radiating portion 14 and the second radiating portion 15 can be reduced. As a result, it is easy to ensure the large connector mounting region A in the housing 4, and the size of the electronic apparatus 21 can be reduced.

Furthermore, as illustrated in FIG. 10, in the structure in which the heat pipes do not intersect each other, the bending angles of the curved portions 16d, 16e, 17d, and 17e of the first and second heat pipes 16 and 17 are likely to be tight (i.e., sharp) (see portions surrounded by one-dot chain lines in FIG. 10).

In contrast, in the embodiment in which the heat pipes intersect each other, as illustrated in FIG. 9, the bending angles of the curved portions 16d, 16e, 17d, and 17e of the first and second heat pipes 16 and 17 can be reduced (see portions surrounded by one-dot chain lines in FIG. 9). When the bending angles of the first and second heat pipes 16 and 17 can be reduced, the length of the first and second heat pipes 16 and 17 can be reduced. As the length of the heat pipe is reduced, heat radiation efficiency is improved. Therefore, according to this structure, heat radiation efficiency can be improved.

In the embodiment, the first heat-generating element 12 and the second heat-generating element 13 are mounted on the same surface of the circuit board 11, and the first heat pipe 16 and the second heat pipe 17 are disposed above the same surface of the circuit board 11. According to this structure, it is possible to provide components requiring a space in the height direction so as to be concentrated on one surface of the circuit board 11, which makes it easy to reduce the thickness of the electronic apparatus 21.

In the embodiment, the energy consumption of the first heat-generating element 12 is greater than that of the second heat-generating element 13. The first heat pipe 16 is disposed closer to the surface of the circuit board 11 than the second heat pipe 17. Therefore, the gradient of the first heat pipe 16 can be set to be less than that of the second heat pipe 17. In this way, the first heat pipe 16 can be shorter than the second heat pipe 17. As a result, the heat radiation efficiency of the first heat-generating element 12 with large energy consumption can be further improved.

In the embodiment, the central portion 16c of the first heat pipe 16 is inclined away from the first fan 18 while extending from the first end portion 16a to the second end portion 16b. According to this structure, as illustrated in FIG. 9, the bending angle between the first radiating portion 14 and the first heat-generating element 12 can be further reduced, and thus the length of the first heat pipe 16 can be further reduced. This holds for the second heat pipe 17.

### Fourth Embodiment

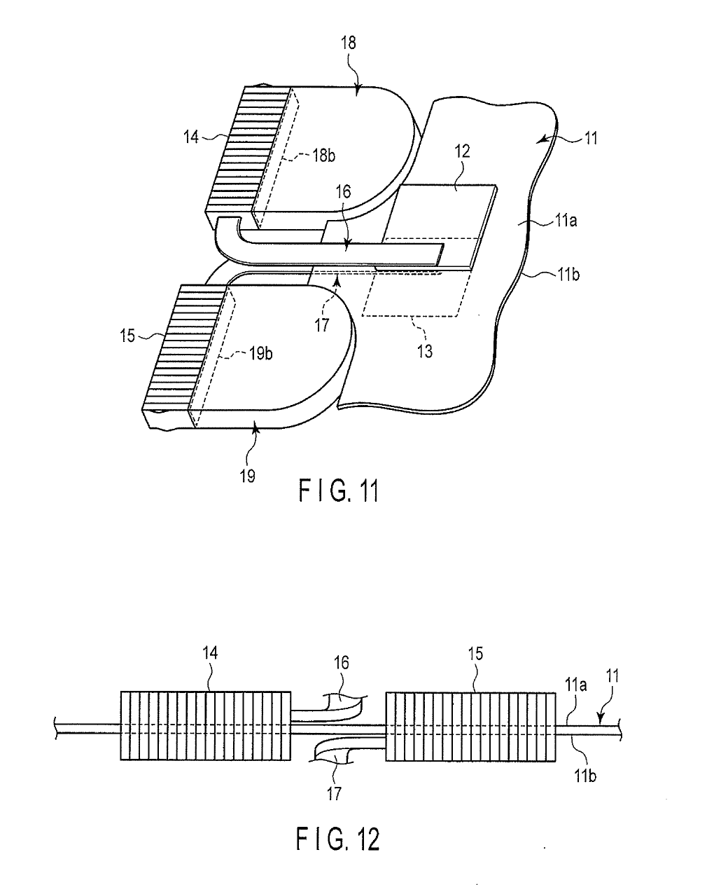

Next, an electronic apparatus 21 according to a fourth embodiment will be described with reference to FIGS. 11 and 12. In the embodiment, components having the same or similar functions as those in the third embodiment are denoted by the same reference numerals, and the description thereof will not be repeated. Structures other than the following structures are the same as those in the third embodiment.

As illustrated in FIGS. 11 and 12, a circuit board 11 includes a first surface 11a and a second surface 11b opposite to the first surface 11a. A first heat-generating element 12 is mounted on the first surface 11a. At least a portion of a first heat pipe 16 faces the first surface 11a. A second heat-generating element 13 is mounted on the second surface 11b. At least a portion of a second heat pipe 17 faces the second surface 11b.

According to this structure, similarly to the third embodiment, the size of the electronic apparatus 21 can be reduced, and the cooling efficiency thereof can be improved.

### Fifth Embodiment

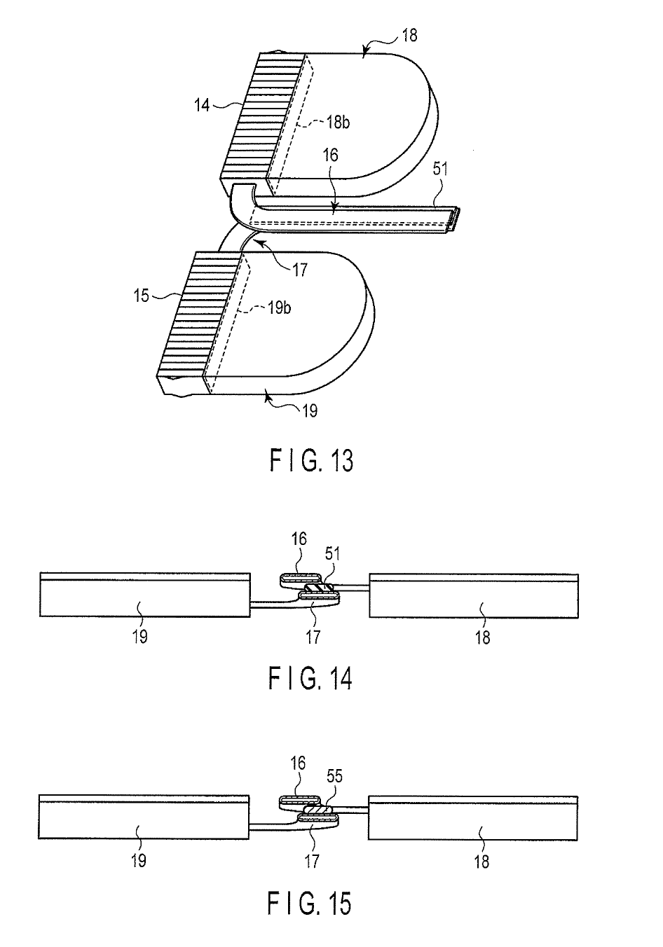

Next, an electronic apparatus 21 according to a fifth embodiment will be described with reference to FIGS. 13 and 14. In the embodiment, components having the same or similar functions as those in the third embodiment are denoted by the same reference numerals, and the description thereof will not be repeated. Structures other than the following structures are the same as those in the third embodiment.

As illustrated in FIGS. 13 and 14, the electronic apparatus 21 according to the embodiment includes a buffer 51 with low thermal conductivity between a first heat pipe 16 and a second heat pipe 17. The buffer 51 is interposed between the first heat pipe 16 and the second heat pipe 17 in at least a portion of the intersection (i.e., intersection area) between the first heat pipe 16 and the second heat pipe 17. For example, the thermal conductivity of the buffer 51 is less than that of the first heat pipe 16 (or the second heat pipe 17). The buffer 51 is, for example, rubber or sponge and has elasticity.

According to this structure, similarly to the third embodiment, the size of the electronic apparatus 21 can be reduced, and the cooling efficiency thereof can be improved. In particular, in the embodiment, the buffer 51 is provided. The provision of the buffer 51 makes it possible to reduce impact (i.e., stress) applied to the heat pipes 16 and 17. In addition, the provision of the buffer 51 makes it possible to ensure the gap between the first and second heat pipes 16 and 17. In this way, the movement of heat between the two heat pipes 16 and 17 can be suppressed, and the first heat radiating system 43 and the second heat radiating system 44 can fulfill the original functions.

### Sixth Embodiment

Next, an electronic apparatus 21 according to a sixth embodiment will be described with reference to FIG. 15. In the embodiment, components having the same or similar functions as those in the third embodiment are denoted by the same reference numerals, and the description thereof will not be repeated. Structures other than the following structures are the same as those in the third embodiment.

As illustrated in FIG. 15, the electronic apparatus 21 according to the embodiment includes a thermally-conductive member 55 (i.e., thermal conductor) between a first heat pipe 16 and a second heat pipe 17. The thermally-conductive member 55 is interposed between the first heat pipe 16 and the second heat pipe 17 in at least a portion of the intersection (i.e., intersection area) between the first heat pipe 16 and the second heat pipe 17. The thermally-conductive member 55 thermally connects the first heat pipe 16 and the second heat pipe 17. The thermally-conductive member 55 has, for example, elasticity.

According to this structure, similarly to the third embodiment, the size of the electronic apparatus 21 can be reduced, and the cooling efficiency thereof can be improved. In particular, in the embodiment, the thermally-conductive member 55 is provided. The provision of the thermally-conductive member 55 makes it possible to disperse heat generated from the heat-generating elements 12 and 13 to the two radiating portions 14 and 15 when one of the first and second radiating portions 14 and 15 does not function well.

### Seventh Embodiment

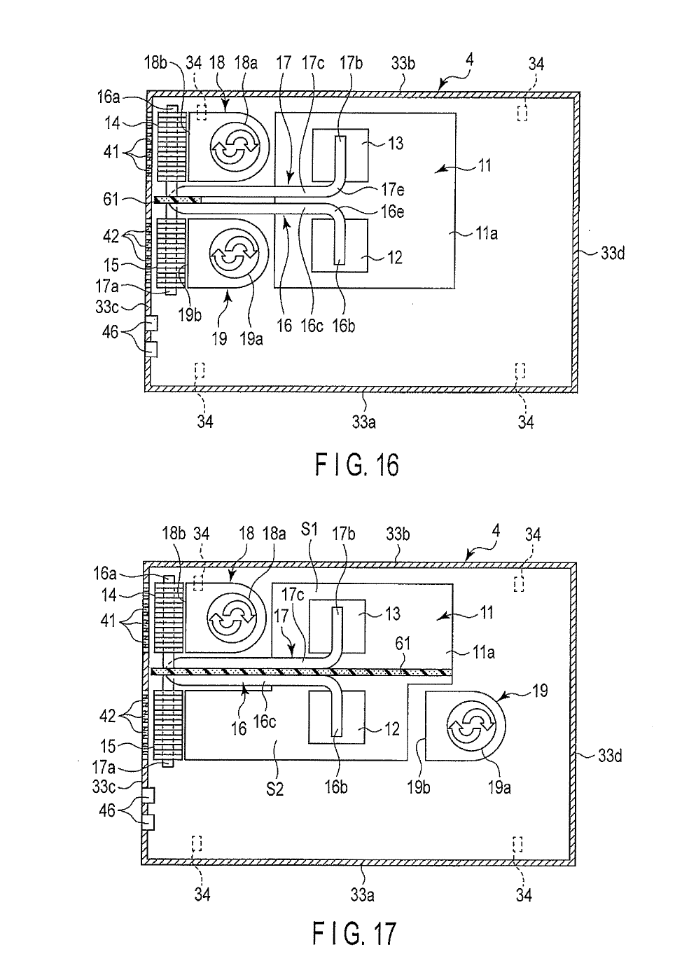

Next, an electronic apparatus 21 according to a seventh embodiment will be described with reference to FIG. 16. In the embodiment, components having the same or similar functions as those in the third embodiment are denoted by the same reference numerals, and the description thereof will not be repeated. Structures other than the following structures are the same as those in the third embodiment.

As illustrated in FIG. 16, the electronic apparatus 21 according to the embodiment includes a wind shielding portion 61 between a first radiating portion 14 and a second radiating portion 15. The wind shielding portion 61 is, for example, a sponge member and is interposed between an upper wall 31 and a lower wall 32 of a housing 4. The wind shielding portion 61 at least partially separates a region in which the first radiating portion 14 is provided and a region in which the second radiating portion 15 is provided in the housing 4.

According to this structure, similarly to the third embodiment, the size of the electronic apparatus 21 can be reduced, and the cooling efficiency thereof can be improved. In particular, in the embodiment, the wind shielding portion 61 is provided. The provision of the wind shielding portion 61 makes it easy for air blown from a first fan 18 to flow to the first radiating portion 14. In addition, it is easy for air blown from a second fan 19 to flow to the second radiating portion 15. In this way, heat radiation efficiency can be improved.

### Eighth Embodiment

Next, an electronic apparatus 21 according to an eighth embodiment will be described with reference to FIG. 17. In the embodiment, components having the same or similar functions as those in the seventh embodiment are denoted by the same reference numerals, and the description thereof will not be repeated. Structures other than the following structures are the same as those in the third embodiment.

As illustrated in FIG. 17, in the embodiment, a first heat-generating element 12 and a portion of a circuit board 11 are disposed between a second radiating portion 15 and a second fan 19. Air blown from the second fan 19 passes around the first heat-generating element 12, thereby taking heat from the first heat-generating element 12.

As illustrated in FIG. 17, the electronic apparatus 21 includes a wind shielding portion 61. The wind shielding portion 61 at least partially separates a first region S1 (i.e., first portion) and a second region S2 (i.e., second portion) in a housing 4. A first radiating portion 14, a first fan 18, first exhaust holes 41, and a second heat-generating element 13 are provided in the first region S1. The second radiating portion 15, the second fan 19, second exhaust holes 42, and the first heat-generating element 12 are provided in the second region S2.

According to this structure, similarly to the third embodiment, the size of the electronic apparatus 21 can be reduced and the cooling efficiency thereof can be improved. In particular, in the embodiment, the first heat-generating element 12 is disposed between the second radiating portion 15 and the second fan 19 and receives air from the second fan 19. The first heat-generating element 12 is cooled by the second fan 19. The air blown from the second fan 19 is heated by the first heat-generating element 12 and is then exhausted to the outside through the second radiating portion 15.

On the other hand, cold air (i.e., air which is not heated by the first heat-generating element 12) is blown from the first fan 18 to the first radiating portion 14 thermally connected to the first heat-generating element 12. In this way, the first heat-generating element 12 can be cooled effectively.

### Ninth Embodiment

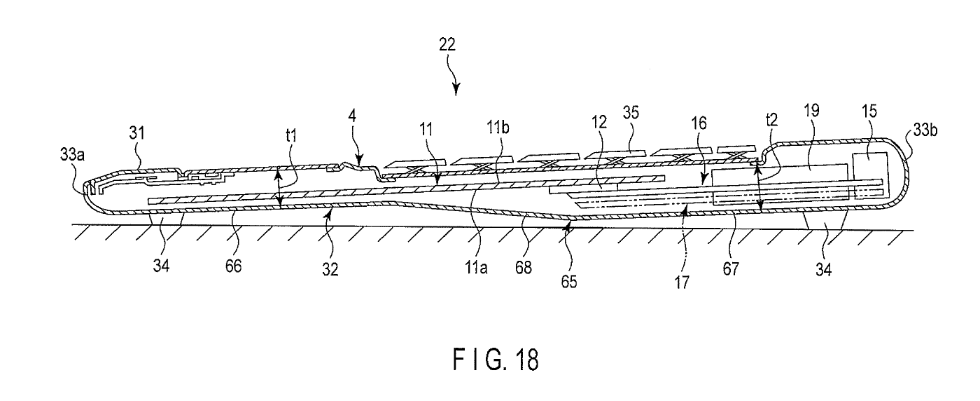

Next, an electronic apparatus 21 according to a ninth embodiment will be described with reference to FIG. 18. In the embodiment, components having the same or similar functions as those in the third embodiment are denoted by the same reference numerals, and the description thereof will not be repeated. Structures other than the following structures are the same as those in the third embodiment.

As illustrated in FIG. 18, a housing 4 according to the embodiment includes a projection 65 which protrudes toward the outside of the housing 4. Specifically, a lower wall 32 of the housing 4 includes a first lower wall 66, a second lower wall 67, and an inclined portion 68. The distance between the first lower wall 66 and an upper wall 31 is a first distance t1, and the first lower wall 66 extends substantially in parallel to the upper wall 31 and a circuit board 11. The distance between the second lower wall 67 and the upper wall 31 is a second distance t2 more than the first distance t1, and the second lower wall 67 extends substantially in parallel to the upper wall 31 and the circuit board 11. The inclined portion 68 is provided between the first lower wall 66 and the second lower wall 67 and connects the first lower wall 66 and the second lower wall 67.

As illustrated in FIG. 18, a first heat pipe 16 and a second heat pipe 17 are disposed between the circuit board 11 and the second lower wall 67. At least a portion of each of the first heat pipe 16 and the second heat pipe 17 is accommodated in the projection 65.

According to this structure, similarly to the third embodiment, the size of the electronic apparatus 21 can be reduced, and the cooling efficiency thereof can be improved. In particular, in the embodiment, at least a portion of each of the first heat pipe 16 and the second heat pipe 17 is accommodated in the projection 65. According to this structure, the thickness of the electronic apparatus 21 can be reduced. A portion of one of the first heat pipe 16 and the second heat pipe 17 may be accommodated in the projection 65.

### Tenth Embodiment

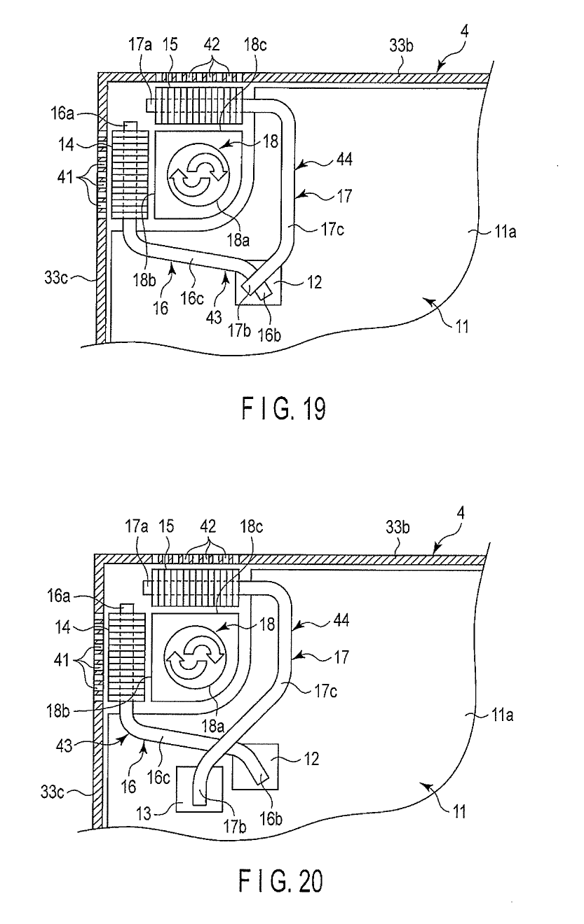

Next, an electronic apparatus 21 according to a tenth embodiment will be described with reference to FIG. 19. In the embodiment, components having the same or similar functions as those in the third embodiment are denoted by the same reference numerals, and the description thereof will not be repeated. Structures other than the following structures are the same as those in the third embodiment.

As illustrated in FIG. 19, in the embodiment, a housing 4 accommodates a circuit board 11, a heat-generating element 12, a first radiating portion 14, a second radiating portion 15, a first heat pipe 16, a second heat pipe 17, and a fan 18.

First exhaust holes 41 are provided in a first side wall 33c. Second exhaust holes 42 are provided in a rear wall 33b. That is, the first exhaust holes 41 and the second exhaust holes 42 are separately provided in two walls which are substantially perpendicular to each other. The first exhaust holes 41 and the second exhaust holes 42 may be provided in other walls.

The fan 18 includes a first discharge hole 18b and a second discharge hole 18c. The first discharge hole 18b faces the first radiating portion 14, and air is blown from the first discharge hole 18b to the first radiating portion 14. The second discharge hole 18c faces the second radiating portion 15, and air is blown from the second discharge hole 18c to the second radiating portion 15. The first heat pipe 16 and the second heat pipe 17 are thermally connected to the heat-generating element 12. For example, the first heat pipe 16 and the second heat pipe 17 intersect each other above the heat-generating element 12.

According to this structure, the size of the electronic apparatus 21 can be reduced.

### Eleventh Embodiment

Next, an electronic apparatus 21 according to an eleventh embodiment will be described with reference to FIG. 20. In the embodiment, components having the same or similar functions as those in the third and tenth embodiments are denoted by the same reference numerals, and the description thereof will not be repeated. Structures other than the following structures are the same as those in the third embodiment. The structures related to a fan 18 and exhaust holes 41 and 42 are the same as those in the tenth embodiment.

As illustrated in FIG. 20, in the embodiment, a housing 4 accommodates a circuit board 11, a first heat-generating element 12, a second heat-generating element 13, a first radiating portion 14, a second radiating portion 15, a first heat pipe 16, a second heat pipe 17, and the fan 18.

The energy consumption of the first heat-generating element 12 is greater than that of the second heat-generating element 13. The second heat-generating element 13 is closer to the first radiating portion 14 than to the second radiating portion 15. The first heat pipe 16 extends between the first radiating portion 14 and the first heat-generating element 12. The second heat pipe 17 has a portion crossing the first heat pipe 16, and extends between the second radiating portion 15 and the second heat-generating element 13.

According to this structure, the size of the electronic apparatus 21 can be reduced. In particular, in the embodiment, the first heat-generating element 12 with large energy consumption is thermally connected to the first radiating portion 14 prior to the second heat-generating element 13. In this way, the length of the first heat pipe 16 can be reduced, and the heat radiation efficiency of the entire apparatus can be improved.

As illustrated in FIG. 20, when an impeller is rotated in the clockwise direction, the amount of air discharged from a first discharge hole 18b is more than that of air discharged from a second discharge hole 18c. That is, the first radiating portion 14 is more likely to be cooled than the second radiating portion 15. Since the first heat-generating element 12 with large energy consumption is preferentially connected to the first radiating portion 14 which is likely to be cooled, the heat radiation efficiency of the entire apparatus can be improved.

### Twelfth Embodiment

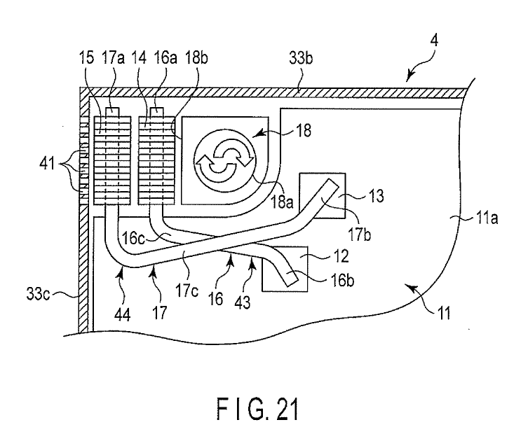

Next, an electronic apparatus 21 according to a twelfth embodiment will be described with reference to FIG. 21. In the embodiment, components having the same or similar functions as those in the third and tenth embodiments are denoted by the same reference numerals, and the description thereof will not be repeated. Structures other than the following structures are the same as those in the third embodiment.

As illustrated in FIG. 21, in the embodiment, a housing 4 accommodates a circuit board 11, a first heat-generating element 12, a second heat-generating element 13, a first radiating portion 14, a second radiating portion 15, a first heat pipe 16, a second heat pipe 17, and a fan 18.

The energy consumption of the first heat-generating element 12 is greater than that of the second heat-generating element 13. The second heat-generating element 13 is closer to the first radiating portion 14 than to the second radiating portion 15. The first heat pipe 16 extends between the first radiating portion 14 and the first heat-generating element 12. The second heat pipe 17 has a portion crossing the first heat pipe 16, and extends between the second radiating portion 15 and the second heat-generating element 13.

As illustrated in FIG. 21, the first radiating portion 14 is closer to a discharge hole 18b of the fan 18 than the second radiating portion 15. Therefore, the first radiating portion 14 is more likely to be cooled than the second radiating portion 15. Since the first radiating portion 14 is close to the fan 18, the first heat pipe 16 is shorter than the second heat pipe 17.

According to this structure, the size of the electronic apparatus 21 can be reduced. In particular, in the embodiment, the first heat-generating element 12 with large energy consumption is thermally connected to the first radiating portion 14 with high heat radiation efficiency prior to the second heat-generating element 13. Therefore, the heat radiation efficiency of the entire apparatus can be improved. The first heat pipe 16 is shorter than the second heat pipe 17. Therefore, the heat radiation efficiency of the first heat-generating element 12 can be improved.

The embodiments are not limited to the above-described embodiments, and the components according to the above-described embodiments may be changed without departing from the scope and gist of the invention. In addition, a plurality of components according to the above-described embodiments may be appropriately combined with each other to form various structures. For example, some of the components according to the above-described embodiments may be removed. Components according to different embodiments may be appropriately combined with each other.

The electronic apparatus to which the third to twelfth embodiments can be applied is not limited to the notebook PC, and the third to twelfth embodiments can be widely applied to, for example, mobile phones including smart phones, slate PCs (tablet terminals), televisions, and other electronic apparatuses.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing comprising a first hole and a second hole;
a display comprising a screen;
a circuit board in the housing, the circuit board electrically connected to the display;
a first radiating portion facing the first hole in the housing;
a second radiating portion facing the second hole in the housing;
a first heat-generating element on the circuit board;
a second heat-generating element on the circuit board, the second heat-generating element being closer to the first radiating portion than to the second radiating portion;
a first heat pipe between the first radiating portion and the first heat-generating element;
a second heat pipe comprising a portion crossing the first heat pipe, the second heat pipe extending between the second radiating portion and the second heat-generating element; and
a first fan configured to blow air to at least one of the first radiating portion and the second radiating portion.

2. The television of claim 1,
wherein the first heat-generating element and the second heat-generating element are on the same surface of the circuit board, and
the first heat pipe and the second heat pipe face the same surface of the circuit board.

3. The television of claim 1,
wherein the energy consumption of the first heat-generating element is greater than that of the second heat-generating element,
the first heat pipe comprises a portion crossing the second heat pipe,
the portion of the first heat pipe is closer to a surface of the circuit board than the second heat pipe, and
the first heat pipe is shorter than the second heat pipe.

4. The television of claim 1, further comprising:
a second fan is configured to blow air to the second radiating portion,
wherein the first fan is configured to blow air to the first radiating portion.

5. The television of claim 1,
wherein the first heat pipe comprises a first end thermally connected to the first radiating portion, a second end thermally connected to the first heat-generating element, and a portion between the first end and the second end, the portion inclined away from the first fan while extending from the first end to the second end.

6. The television of claim 1, further comprising:
a buffer between the first heat pipe and the second heat pipe at an intersection between the first heat pipe and the second heat pipe.

7. The television of claim 1,
wherein the housing comprises a projection toward an outside of the housing, and
at least a portion of the second heat pipe is in the projection.

8. The television of claim 1, further comprising:
a thermal conductor between the first heat pipe and the second heat pipe at an intersection between the first heat pipe and the second heat pipe.

9. The television of claim 1,
wherein the circuit board comprises a first surface and a second surface, the second surface opposite to the first surface,
the first heat-generating element is on the first surface,
at least a portion of the first heat pipe faces the first surface,
the second heat-generating element is on the second surface, and
at least a portion of the second heat pipe faces the second surface.

10. An electronic apparatus comprising:
a housing;
a first radiating portion in the housing;
a second radiating portion in the housing;
a first heat pipe thermally connected to the first radiating portion;
a second heat pipe comprising a portion crossing the first heat pipe, the second heat pipe thermally connected to the second radiating portion; and
a fan configured to blow air to at least one of the first radiating portion and the second radiating portion.
